(19) United States
(12) Patent Application Publication
(10) Pub. No.: US 2017/0222282 A1
(43) Pub. Date: Aug. 3, 2017

(54) BATTERY DIAGNOSTIC SENSOR UNIT

(71) Applicant: Lear Corporation, Southfield, MI (US)

(72) Inventors: Jose Antonio CUBERO PITEL, Valls (ES); Luis Miguel MUNOZ, Valls (ES); Josep Maria ROSET RUBIO, Valls (ES)

(21) Appl. No.: 15/011,966

(22) Filed: Feb. 1, 2016

(51) Int. Cl. H01M 10/42; H01M 10/48; G07C 5/08; B60L 11/18; G01R 31/36; G01R 31/00

(52) U.S. Cl. CPC H01M 10/4257; G01R 31/3696; G01R 31/006; G07C 5/0808; B60L 11/1851; H01M 10/48; H01M 2010/4271; H01M 2010/4278; H01M 2220/20

(57) ABSTRACT

A battery monitoring system that may be used to measure/monitor any number of battery operating conditions, including those associated with a vehicle battery. The system may be configured to interconnect a battery post that receives energy from the battery and a cable that electrically connects the battery to a vehicle.

### TECHNICAL FIELD

The present disclosure relates to battery diagnostic sensors, such as the type for connecting to battery posts and having capabilities for sensing and/or reporting battery operating conditions.

### BACKGROUND

Hybrid and non-hybrid vehicles may be equipped with energy storage devices, such as batteries for powering the vehicle and other devices. A battery monitoring system (BMS) may include a battery diagnostic sensor unit that may be connected to a battery post and configured to sense battery operating conditions. These type of battery diagnostic sensor units may be employed in automotive vehicles having lead-acid or some other type of battery or similar energy storage device. The battery diagnostic sensor units may be advantageous in reporting the battery operating conditions to a junction box or other vehicle system controller.

### SUMMARY

One or more embodiments of the present disclosure are directed to a battery monitoring system for use with a battery used to power electronic devices within a vehicle. The battery may have a ledge proximate to a battery post. The system may comprise a battery clamp including a terminal adapter at one end and a shunt adapter at another end. The terminal adapter may have a compressively tightened connection to electrically connect to the battery post.

The system may further comprise a shunt having a first conductive portion, a second conductive portion, and a resistive portion disposed between the first conductive portion and the second conductive portion. The first conductive portion of the shunt may be attached to a first end of the shunt adapter and the second conductive portion of the shunt may be attached to a conducting portion of a vehicle cable. The cable may be used to carry energy between the battery and the vehicle.

The system may further comprise a printed circuit board (PCB) having a battery monitoring circuit configured to measure a voltage drop between the first conductive portion and the second conductive portion of the shunt. The system may further comprise a housing enclosing the PCB and at least a portion of the shunt. The housing may include a tab slot that receives a tab formed at a second end of the shunt adapter.

The first conductive portion of the shunt may be attached to the first end of the shunt adapter using a soldering process, a welding process, or a brazing process. The system may further include a signal connector attached to the PCB and in communication with the battery monitoring circuit. The signal connector may provide an interface that sends signals to and receives signals from a network vehicle element.

The tab may be co-planar with the second end of the shunt adapter. Alternatively, the tab may be angled downward from a main plane of the shunt adapter. The housing may be formed from an epoxy molded compound molded around the PCB and the portion of the shunt. The shunt adapter may include a bend between the first end and the second end such that the first end and the second end of the shunt adapter are in offset, parallel planes.

One or more additional embodiments of the present disclosure are directed to a battery diagnostic sensor (BDS) unit for use between a vehicle battery and a vehicle cable. The vehicle cable may be used for transferring energy between the vehicle battery and one or more electronic devices included within a vehicle. The BDS unit may comprise a shunt, a printed circuit board (PCB), a signal connector, a housing, and a battery clamp.

The shunt may have a resistive portion disposed between a first conductive portion and a second conductive portion. The second conductive portion may be connected to an electrically conducting portion of the vehicle cable. The PCB may have first and second footprints respectively connected to the first and second conductive portions of the shunt. The PCB may include a battery monitoring circuit measuring a voltage drop between the first and second footprints. The signal connector may be attached to the PCB and in communication with the battery monitoring circuit. The signal connector may provide an interface that sends signals to and receives signals from a network vehicle element. The housing may enclose the PCB and at least a portion of the shunt.

The battery clamp may be composed of a continuous piece of material. The battery clamp may include (i) a terminal adapter having a cylindrically shaped, compressively tightened portion to electrically connect to a post of the battery; and (ii) a shunt adapter extending from the terminal adapter. The shunt adapter may affix the battery clamp to a remainder of the BDS unit at a first fixation point and a second fixation point. The shunt adapter may have a first end electrically connected to the first conductive portion of the shunt at the first fixation point and a second end having a tab inserted into a corresponding tab slot in the housing at the second fixation point.

The first end of the shunt adapter may be electrically connected to the first conductive portion of the shunt using one of a soldering, welding, or brazing process. The tab may be co-planar with the second end of the shunt adapter. Alternatively, the tab may be angled downward from a main plane of the second end of the shunt adapter. The housing may be formed from an epoxy molded compound molded around the PCB and the portion of the shunt. The shunt adapter may include a bend between the first end and the second end such that the first end and the second end of the shunt adapter are in offset, parallel planes.

The second conductive portion of the shunt may be connected to an electrically conducting portion of the vehicle cable via a connecting element. The connecting element may have a proximal end including at least a first clamping portion secured to the electrically conducting portion of the vehicle cable. The connecting element may have a distal end electrically connected to the second conductive portion of the shunt.

One or more additional embodiments of the present disclosure are directed to a method for assembling a battery diagnostic sensor (BDS) unit. The method may comprise providing a PCB having at least a battery monitoring circuit; soldering a shunt and a signal connector to the PCB; forming a housing around the PCB and at least portions of the shunt and the signal connector using a moldable compound; and attaching a battery clamp to the BDS unit at a first fixation point and a second fixation point, wherein only one of the first and second fixation points includes an electrical connection to the shunt.

Attaching the battery clamp to the BDS unit may include inserting a tab formed in a battery clamp into a tab slot formed in the housing at the second fixation point and electrically connecting a shunt adapter to the shunt at the first fixation point. The shunt adapter may be electrically connected to a first conductive portion of the shunt. The method may further comprise electrically connecting a vehicle cable to a second conductive portion of the shunt. The first conductive portion and the second conductive portion of the shunt may be separated by a resistive portion of the shunt. Electrically connecting the shunt adapter to the shunt may comprise one of soldering, welding, or brazing the shunt adapter to the shunt.

### BRIEF DESCRIPTION OF THE DRAWINGS

FIG. 1 is a perspective view of a battery monitoring system, according to one or more embodiments of the present disclosure;

FIG. 2 is an exemplary, exploded view of a battery diagnostic sensor (BDS) unit, according to one or more embodiments of the present disclosure;

FIG. 3a is a perspective view of the BDS unit with an overmold housing, according to one or more embodiments of the present disclosure;

FIG. 3b is a perspective view of the BDS unit in FIG. 3a showing a battery clamp without the overmold housing;

FIG. 4 is a perspective view of an alternate battery clamp for a BDS unit, according to one or more embodiments of the present disclosure;

FIG. 5 is a top plan view of the battery clamp in FIG. 4 secured to a housing, according to one or more embodiments of the present disclosure;

FIG. 6 is a perspective view illustrating the assembled BDS unit with the battery clamp shown in FIG. 4, according to one or more embodiments of the present disclosure; and

FIG. 7 is a flow chart illustrating an assembly process of a BDS unit, according to one or more embodiments of the present disclosure.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

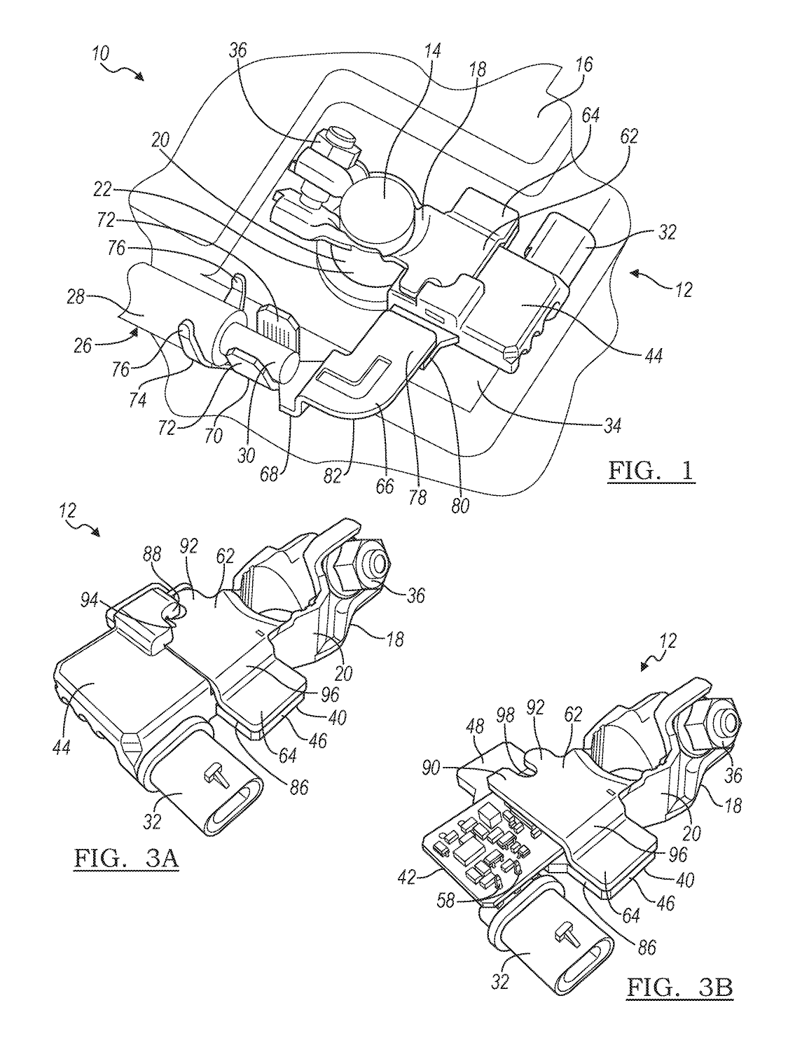

FIG. 1 illustrates a battery monitoring system (BMS) 10 in accordance with one or more objects of the present disclosure. A battery diagnostic sensor (BDS) unit 12 may be included and configured for connecting to a battery post 14 of a battery 16, such as a lead-acid or other battery commonly employed within vehicles. The battery 16 is used to power electronic devices within a vehicle. The BDS unit 12 may be securely connected to the battery post 14 with a battery clamp 18 via compressive tightening of a terminal adapter 20 at one end of the battery clamp 18 or through another suitable connection. The BDS unit 12 may be configured or otherwise programmed to support any number of sensor operations, such as but not limited to measuring/sensing current, voltage, and temperatures associated with the battery 16.

The battery clamp 18 may comprise a continuous piece of tinned brass or other material suitable for conducting electricity from the battery 16. The battery clamp 18, as described below in more detail, may extend relative to an outward clamping end that hosts the terminal adaptor 20 used to connect to the battery post 14. The terminal adapter 20 is configured for attachment to a cylindrical battery post 14 for exemplary purposes. Accordingly, the terminal adapter 20 may include a cylindrically shaped, compressively tightened portion 22. However, any type of connection to the battery 16 may be used.

The BDS unit 12 may interface with a cable, wire, or other element 26 suitable for conducting electricity to another element within the vehicle, such as a vehicle chassis (not shown), grounding element, etc. The cable 26 may be suitable for use in conducting energy between the battery 16 and the vehicle element. The cable 26 may include an outer insulated portion 28 surrounding a copper or other suitable electrically conducting material 30.

The BDS unit 12 may further include a signal connector 32 that provides a network interface for interfacing signals with a network vehicle element (not shown), such as to a vehicle system controller, junction box, bus, network etc. The signal connector 32 may be used to interface any number of signals between the BDS unit 12 and the vehicle system controller or other network vehicle element, i.e., any element not intended to exchange current directly with the battery 16. For example, one or two-way communications may be established with the BDS unit 12 to facilitate any number of operations, such as but not limited operations associated with sensing and measuring current, voltage, temperature, and other operating parameters of the battery 16.

As shown in FIG. 1, the BDS unit 12 may be sized and shaped to fit within a ledge or niche 34 of the battery 16. The BDS unit 12 may rest within the ledge 34 so that no portion of the BDS unit 12 extends above a top side of the battery 16. This can be helpful in reducing packaging and limiting space restrictions and help prevent rotation when mounting the BDS unit 12. As also shown, the terminal adapter 20 may include an adapter screw 36, which is slightly angled in an upright direction to facilitate tightening. The adapter screw 36 may be angled in any direction, both laterally and vertically and is not intended to be limited to the illustrated positions.

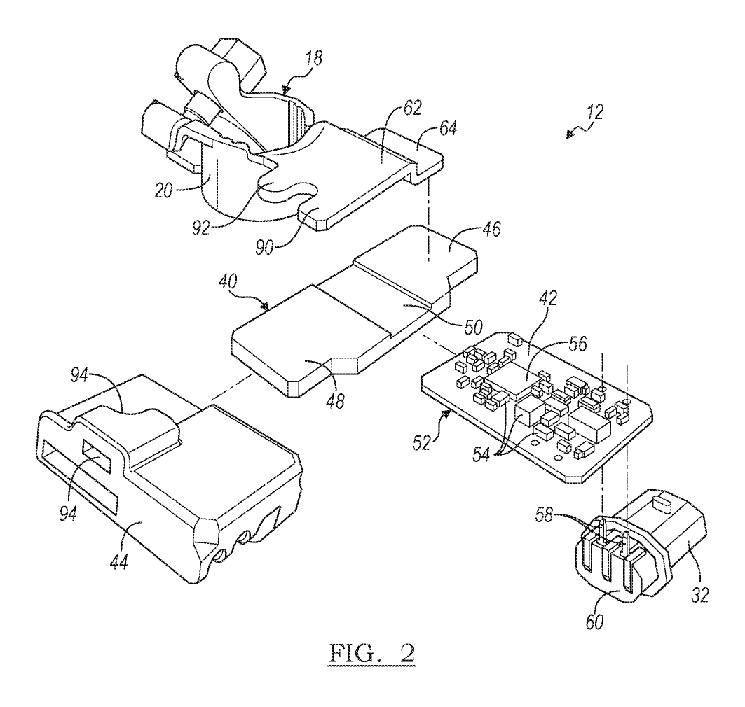

FIG. 2 is an exemplary, exploded view of the BDS unit 12. As shown, the BDS unit 12 may further include a shunt 40, a printed circuit board (PCB) 42, and a housing 44. The shunt 40 may comprise any material having properties sufficient to facilitate electrical connectivity between the battery clamp 18 and the cable 26. The shunt 40 is shown as a bi-metallic object having a first conductive portion 46, a second conductive portion 48, and a resistive portion 50. The first and second conductive portions 46-48 may comprise a conductive copper alloy, while the resistive portion 50 may comprise a resistive copper alloy, such as manganin. The first and second conductive portions 46-48 correspond with the ends of the shunt 40 and the resistive portion 50 may be arranged therebetween such that current must flow from through the first conductive portion 46, through the resistive portion 50, and finally through the second conductive portion 48.

The resistive portion 50 may be used as a measuring element suitable for conducting high currents. Sensing features may be included within or outside the boundaries of the resistive portion 50 for use in facilitating sensing of a voltage drop therebetween. The known resistive characteristics of the resistive portion 50, such as the resistive copper alloy, may be used in conjunction with the voltage drop to determine current flow through the shunt 40. In this manner, the BDS unit 12 is able to sense voltage and current associated with the battery 16. The known resistivity of the resistive portion 50 can be helpful in assuring the accuracy and consistency of the current calculations. Of course, the shunt 40 may utilize any number of other suitable materials as well, including making the shunt 40 out of a single material/composition, i.e., without the bi-metallic composition.

The PCB 42 may be used to assess battery operations. Accordingly, the PCB 42 may be electrically connected to the shunt 40. According to one or more embodiments, the PCB 42 may be directly connected or welded to the shunt 40, for example, using a reflow soldering process. Alternatively, the PCB 42 may include connection tabs (not shown) that can be welded or otherwise electrically secured to the shunt 40. The PCB 42 may include footprints extending over a portion of the first and second conductive portions 46-48 of the shunt 40 to facilitate measuring the voltage drop across the resistive portion 50.

The PCB 42 may include any number of sensors and circuitry or other electrical components to form a PCB sub-assembly 52. For the sake of simplicity, reference to the PCB 42 may be considered a reference to the PCB sub-assembly 52 with electrical components 54 attached. The sensors and circuitry of the PCB 42 may form at least a battery monitoring circuit 56. Accordingly, the PCB 42 may perform any number of logical functions associated with determining the operating conditions of the battery 16 or other operations associated with or based on the BDS unit 12 and its function and performance. For example, the PCB 42 may include a temperature sensor (not shown) for sensing connector temperature and/or battery temperature. A pair of connector pins 58 may be integrated with the signal connector 32 to facilitate an electrical connection to the BDS unit 12 via the PCB 42.

The temperature sensor may be used to sense the battery temperature as a function of the terminal adapter temperature. This may include establishing a thermal coupler or other element (not shown) between the terminal adapter 20 and the PCB 42 so as to facilitate temperature sensing. A negative or positive temperature coefficient element may be included proximate the thermal coupler to facilitate sensing the temperature. The PCB 42 is illustrated for exemplary purposes and without intending to limit the scope and contemplation of the present disclosure. The present disclosure fully contemplates the use of any type of logically functioning processing element, such as but not limited to a discrete or integrated circuit, having properties sufficient to facilitate determining battery operating conditions, which may or may not be included on a PCB 42.

The housing 44 may be included around the PCB 42 and at least the resistive portion 50 of the shunt 40. The housing 44 may also enclose a portion 60 of the signal connector 32 containing the connector pins 58. The housing 44 may comprise a non-conducting material configured for covering a portion of the battery clamp 18 and shunt 40 extending between the battery post 14 and the vehicle cable 26. For instance, the housing 44 may be formed from a moldable compound once the shunt 40 and signal connector 32 are soldered to the PCB 42. For example, an epoxy molding compound may be used to form the housing 44. The housing 44 may be used to electrically isolate the shunt 40 and battery clamp 18.

FIG. 3a is a perspective view of the BDS unit 12 with the overmold housing 44, while FIG. 3b shows the same view without the overmold housing present for illustrative purposes. FIGS. 3a and 3b illustrate the shunt 40 connected to the battery clamp 18 in accordance with one or more embodiments of the present disclosure. The battery clamp 18 may further include a shunt adapter 62 adjacent to the terminal adapter 20. The first conductive portion 46 of the shunt 40 may be connected, such as by welding, soldering, brazing, or other fastening, to a first end 64 of the shunt adapter 62. The second conductive portion 48 of the shunt 40 may be connected directly to the cable 26 or indirectly to the cable 26 via a connecting element, 66 as shown in FIG. 1. In the case of a direct connection, wire strands from the cable 26 may be soldered to the second conductive portion 48 of the shunt 40. A soldering machine or other soldering or welding element may be configured to compress the wires from their circular shape within the cable 26 to a flatter shape more suitable for fastening to the shunt 40. Once the wires are fastened to the shunt 40, or in the same assembly process, the wires may be bent to form the right angle with the shunt 40.

Referring back to FIG. 1, the electrical connection between the cable 26 and shunt 40 via the connecting element 66 is illustrated. The connecting element 66 is formed from an electrically conductive material. The connecting element 66 may include a proximal 68 end having at least a first clamping portion 70 that may be connected to the conducting material 30 of the cable 26 that extends beyond the insulated portion 28. The first clamping portion 70 may include opposed fingers 72 defining an opening for receipt of the cable 26. The first clamping portion 70 may be bendable, with a crimp tool or other feature, to compressively connect to the inner, conducting material 30 of the cable 26.

The proximal end 68 of the connecting element 66 may further include a second clamping portion 74 that may be connected to the insulated portion 28 of the cable 26. The second clamping portion 74 may also include opposed fingers 76 defining an opening for receipt of the cable 26. The second clamping portion 74 may likewise be bendable, with a crimp tool or other feature, to compressively connect to the insulating portion 28 of the cable 26. This connection may help reduce vibratory susceptibility of the connecting element 66. The second clamping portion 74 is shown to include the opposed fingers 76 for exemplary purposes only. The second clamping portion 74 may include any shape or configuration suitable to providing a compressive or other connection between the connecting element 66 and the cable 26. For example, the second clamping portion 74 may include a C-shaped configuration where the outer portions of the C-shape are compressed against the cable 26.

The connecting element 66 may further include a distal end 78 having a connecting surface 80 for electrically connecting to the second conducting portion 48 of the shunt. Similar to the shunt adapter 62, the connecting element 66 may be electrically connected to the shunt 40 by a welding, soldering, brazing, or other fastening operation. According to one or more embodiments, the connecting element 66 may include a bend 82 between the proximal end 68 and the distal end 78, such as the 90 degree bend shown in FIG. 1. The bend 82 in the connecting element 66 may orient the cable 26 in close proximity to the battery 16 and avoid interference with other vehicle components.

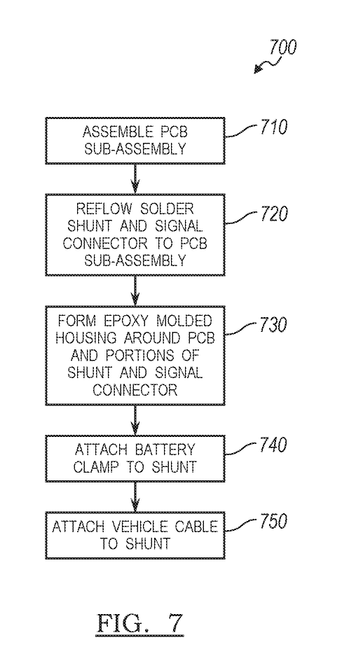

In addition to the connection methods described above, other methods may be employed for connecting the vehicle cable 26 to the shunt 40. For instance, the second conductive portion 48 of the shunt 40 may include an orthogonally extending screw 84 (FIG. 6). Accordingly, the vehicle cable 26 may be attached to the shunt 40 via a connective element, such as a terminal, adapted to be secured to the screw 84 (not shown).

The battery clamp 18 may be electrically connected at one end to the battery post 14 via the terminal adapter 20. At the other end of the battery clamp 18, the first end 64 of the shunt adapter 62 may be electrically connected to the first conductive portion 46 of the shunt 40. The battery clamp 18 and the shunt 40 may be connected to the vehicle chassis or other ground element by cable 26, as previously described, namely via a direct or indirect connection between the cable 26 and the second conductive portion 48 of the shunt 40. This allows the BDS unit 12 to exchange current between the vehicle cable 26 and the battery post 14 by way of the shunt 40 and the battery clamp 18, but without any direct electrical connection between the terminal adapter 20 and the vehicle cable 26.

As previously described, the housing 44 may be included around a portion of the shunt 40 and the PCB 42 used to assess battery operations. The housing 44 may comprise a non-conducting material configured for covering a portion of the shunt adapter 62 and shunt 40 extending between the battery post 14 and the vehicle cable 26. For instance, the housing 44 may be formed from an epoxy molding compound once the shunt 40 and signal connector 32 are soldered to the PCB 42. The housing 44 may be used to electrically isolate the shunt 40 and battery clamp 18, except where the shunt 40 is electrically fastened to the shunt adapter 62 of the battery clamp 18.

The battery clamp 18 may be a stamped from a single sheet of electrically conducting material into the illustrated configuration. Alternatively, the battery clamp 18 may be forged from die-cast materials. According to one or more embodiments, the battery clamp 18 may be shaped so that only one soldering point is needed for fixation to the BDS unit 12. As previously described, the sole soldering point may occur at an interface 86 (or first fixation point) between the first end 64 of the shunt adapter 62 and the first conducting portion 46 of the shunt 40.

As shown in FIGS. 3a and 3b, the battery clamp 18 may be further secured to the remainder of the BDS unit 12 at a second fixation point 88 that is not soldered or welded to the shunt 40. The second fixation point 88 may be realized by fitting a tab 90 formed at a second end 92 of the shunt adapter 62 into a corresponding tab slot 94 formed in the overmold housing 44. Accordingly, the second end 92 of the shunt adapter 62 is not affixed directly to the shunt 40. This avoids a second soldering/welding step, screw process step, riveting step, or the like. The two fixation points 86-88 described adequately secure the battery clamp 18 to the BDS unit 12 using, for example, a single soldering step.

As shown in FIG. 3b, shunt adapter 62 may include a bend 96 between its first end 64 and second end 92. This may permit the second end 92 of the shunt adapter 62 to extend above the PCB 42 and shunt 40 in a plane generally parallel to the shunt 40. Accordingly, the first end 64 of the shunt adapter 62 and the second end 92 of the shunt adapter 62 may extend along offset, yet parallel planes. The second end 92 of the shunt adapter 62 may include a cutout region 98 that forms the tab 90. The tab 90 may be aligned with the tab slot 94 in the housing 44. During assembly, the tab 90 may be inserted into the tab slot 94 to form the second fixation point 88 for securing the battery clamp 18 to the BDS unit 12. The first end 64 of the shunt adapter 62 may be subsequently soldered or welded to the first conducting portion 46 of the shunt 40 to form the first fixation point 86.

As shown in FIGS. 3a and 3b, the tab 90 is generally rectangular and is generally co-planar with the second end 92 of the shunt adapter 62. According to one or more alternate embodiments of the present disclosure, the tab shape, angle and/or direction may be varied without departing from the scope of the present disclosure. Various tab configurations may result in corresponding adaptations to the tab slot 94 in the housing 44 so that it remains in alignment with the tab 90. Accordingly, the tab 90 and tab slot 94 may be configured in such a way that the tab 90 may be inserted into the tab slot 94 regardless of tab orientation.

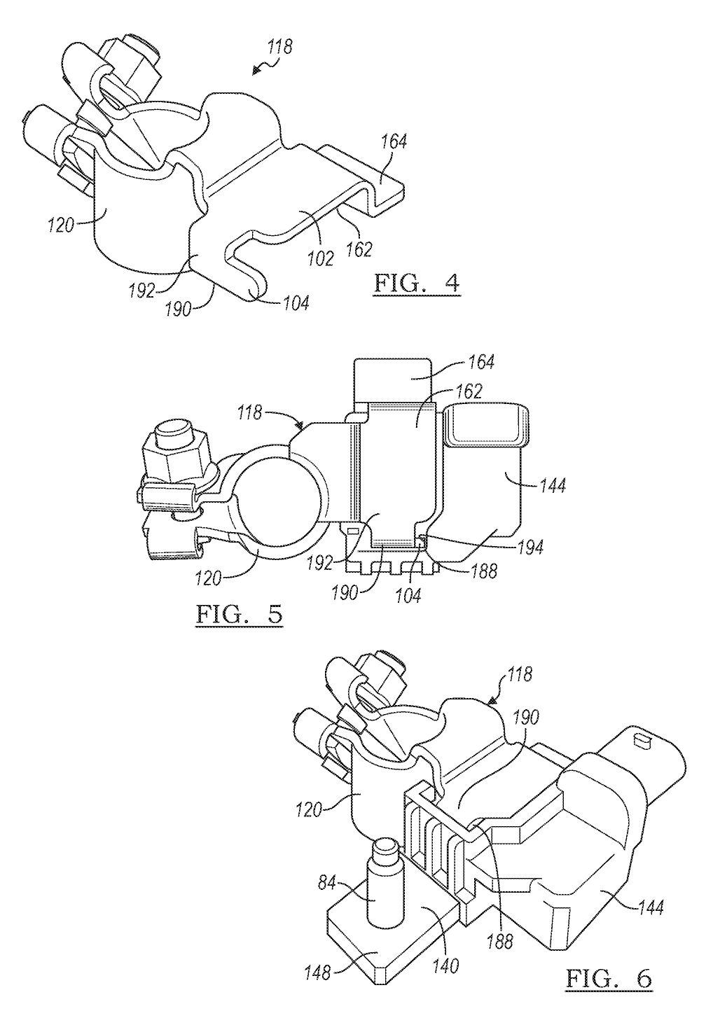

FIGS. 4-6 illustrate an exemplary, alternative tab configuration according to one or more embodiments of the present disclosure. FIG. 4 is a perspective view of an alternate battery clamp 118 having a terminal adapter 120 and a shunt adapter 162. The terminal adapter 120 and a first end 164 of the shunt adapter 162 may be similar to corresponding elements in the battery clamp 18 illustrated in FIGS. 1-3b. The second end 192 of the shunt adapter 162 may include the alternate tab configuration. In particular, the second end 192 of the shunt adapter 162 may include a tab 190 formed into an L-shaped leg that extends downward from a main plane 102 of the shunt adapter 162 in the direction of the shunt.

FIG. 5 is a top plan view of the battery clamp 118 secured to a housing 144. As shown in FIG. 5, the housing 144 may include a corresponding tab slot 194 in which an extension 104 of the L-shaped leg may be inserted for securing the battery clamp 118 to the BDS unit 12 at a second fixation point 188. FIG. 6 is a perspective view illustrating the assembled BDS unit 12 with the battery clamp 118 having the alternate tab configuration. FIG. 6 also illustrates an alternate shunt configuration where, as previously described, a second conductive portion 148 of a shunt 140 includes a screw 84 that may be employed for connecting the shunt 140 to the vehicle cable 26, which in turn may be connected to the vehicle chassis or other grounding element of the vehicle.

The shunt described above in all embodiments of the present disclosure is shown to be a relatively planar shunt. However, any type of shunt having any type of shape, including a shunt having a cylindrical shape, may be employed. Further, the present disclosure fully contemplates any number of connection methods to facilitate electrically connecting the PCB 42 to the shunt 40 and the use of any type of connector or soldering method to facilitate connecting to a cylindrical, planar, or other shaped shunt.

With reference to FIG. 7, an exemplary method 700 of assembly of the BDS unit 12 is illustrated. At step 710, electrical components 54 (e.g., sensors and circuitry) are mounted to the PCB 42 to form the PCB sub-assembly 52. The electrical components 54 may be surface mount components, through hole components, or a combination of both. Moreover, the electrical components 54 may be attached to the PCB 42 by reflow soldering, wave soldering, or manual soldering. Once the PCB sub-assembly 52 is assembled, the shunt 40 and signal connector 32 may be soldered to the PCB sub-assembly 52 using, for example, reflow soldering, as provided at step 720.

At step 730, the housing 44 made from an epoxy molded compound may be formed around the PCB 42 and portions of the shunt 40 and signal connector 32. The housing 44 may vibrationally and electrically isolate and waterproof the PCB 42, which is beneficial in enhancing system integrity against contaminates, water, debris, etc. The housing 44 may enclose the PCB 42 and at least the resistive portion 50 of the shunt 40. It may also encase the connector pins 58 attaching the signal connector 32 to the PCB 42. The housing 44 may be injection molded to form a particular shape around the PCB 42. The housing 44 may be molded such that it includes the tab slot 94 for receiving the tab 90 of the battery clamp 18 at the second fixation point 88.

To that end, the battery clamp 18 may be attached to the shunt 40 at step 740. In particular, the tab 90 at the second end 92 of the shunt adapter 62 may be inserted into the tab slot 94 in the housing 44. The first end 64 of the shunt adapter 62 may then be electrically affixed to the first conductive portion 46 of the shunt 40 as previously described (e.g., using a soldering, welding, or brazing process, etc.). Next, the vehicle cable 26 may be attached to the shunt 40, at step 750. For example, the proximal end 68 of the connecting element 66 may be crimped to the cable 26 as previously described. The distal end 78 of the connecting element 66 may then be soldered to the second conductive portion 48 of the shunt 40. Alternatively, the cable 26 may be directly soldered to the second conductive portion 48 of the shunt 40 or attached to a screw 84 as previously described.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A battery monitoring system for use with a battery used to power electrical devices within a vehicle, the battery having a battery post, the system comprising:
a battery clamp including a terminal adapter at one end and a shunt adapter at another end, the terminal adapter having a compressively tightened connection to electrically connect to a battery post;
a shunt having a first conductive portion, a second conductive portion, and a resistive portion disposed between the first conductive portion and the second conductive portion, the first conductive portion of the shunt attached to a first end of the shunt adapter and the second conductive portion of the shunt attached to a conducting portion of a vehicle cable, the cable being used to carry energy between the battery and the vehicle;
a printed circuit board (PCB) having a battery monitoring circuit configured to measure a voltage drop between the first conductive portion and the second conductive portion of the shunt; and
a housing enclosing the PCB and at least a portion of the shunt, the housing including a tab slot that receives a tab formed at a second end of the shunt adapter.

2. The system of claim 1, wherein the first conductive portion of the shunt is attached to the first end of the shunt adapter using a soldering process.

3. The system of claim 1, wherein the first conductive portion of the shunt is attached to the first end of the shunt adapter using a welding process.

4. The system of claim 1, wherein the first conductive portion of the shunt is attached to the first end of the shunt adapter using a brazing process.

5. The system of claim 1, further comprising a signal connector attached to the PCB and in communication with the battery monitoring circuit, the signal connector providing an interface that sends signals to and receives signals from a network vehicle element.

6. The system of claim 1, wherein the tab is co-planar with the second end of the shunt adapter.

7. The system of claim 1, wherein the tab is angled downward from a main plane of the shunt adapter.

8. The system of claim 1, wherein the housing is formed from an epoxy molded compound molded around the PCB and the portion of the shunt.

9. The system of claim 1, wherein the shunt adapter includes a bend positioned between the first end and the second end to cause the first end and the second end of the shunt adapter to be in offset, parallel planes.

10. A battery diagnostic sensor (BDS) unit for use between a vehicle battery and a vehicle cable, the vehicle cable being used for transferring energy between the vehicle battery and one or more electrical devices included within a vehicle, the BDS unit comprising:
a shunt having a resistive portion disposed between a first conductive portion and a second conductive portion, the second conductive portion connected to an electrically conducting portion of a vehicle cable;
a printed circuit board (PCB) having first and second footprints respectively connected to the first and second conductive portions of the shunt, the PCB including a battery monitoring circuit measuring a voltage drop between the first and second footprints;
a signal connector attached to the PCB and in communication with the battery monitoring circuit, the signal connector providing an interface that sends signals to and receives signals from a network vehicle element;
a housing enclosing the PCB and at least a portion of the shunt; and
a battery clamp composed of a continuous piece of material, the battery clamp including:
(i) a terminal adapter having a cylindrically shaped, compressively tightened portion to electrically connect to a post of the battery; and
(ii) a shunt adapter extending from the terminal adapter, the shunt adapter affixing the battery clamp to a remainder of the BDS unit at a first fixation point and a second fixation point, the shunt adapter having a first end electrically connected to the first conductive portion of the shunt at the first fixation point and a second end having a tab inserted into a corresponding tab slot in the housing at the second fixation point.

11. The BDS unit of claim 10, wherein the first end of the shunt adapter is electrically connected to the first conductive portion of the shunt using one of a soldering, welding, or brazing process.

12. The BDS unit of claim 10, wherein the tab is co-planar with the second end of the shunt adapter.

13. The BDS unit of claim 10, wherein the tab is angled downward from a main plane of the second end of the shunt adapter.

14. The BDS unit of claim 10, wherein the housing is formed from an epoxy molded compound molded around the PCB and the portion of the shunt.

15. The BDS unit of claim 10, wherein the shunt adapter includes a bend between the first end and the second end to position the first end and the second end of the shunt adapter are in offset, parallel planes.

16. The BDS unit of claim 10, wherein the second conductive portion of the shunt is connected to an electrically conducting portion of the vehicle cable via a connecting element, the connecting element having a proximal end including at least a first clamping portion secured to the electrically conducting portion of the vehicle cable, the connecting element having a distal end electrically connected to the second conductive portion of the shunt.

17. A method for assembling a battery diagnostic sensor (BDS) unit comprising:
providing a PCB having at least a battery monitoring circuit;
soldering a shunt and a signal connector to the PCB;
forming a housing around the PCB and at least portions of the shunt and the signal connector using a moldable compound; and
attaching a battery clamp to the BDS unit at a first fixation point and a second fixation point, wherein only one of the first and second fixation points includes an electrical connection to the shunt.

18. The method of claim 17, wherein attaching the battery clamp to the BDS unit comprises:
inserting a tab formed in a battery clamp into a tab slot formed in the housing at the second fixation point; and
electrically connecting a shunt adapter to the shunt at the first fixation point.

19. The method of claim 18, wherein the shunt adapter is electrically connected to a first conductive portion of the shunt, the method further comprising:
electrically connecting a vehicle cable to a second conductive portion of the shunt, the first conductive portion and the second conductive portion of the shunt being separated by a resistive portion of the shunt.

20. The method of claim 18, wherein electrically connecting the shunt adapter to the shunt comprises one of soldering, welding, or brazing the shunt adapter to the shunt.
